(19) United States
(12) Patent Application Publication
(10) Pub. No.: US 2026/0213440 A1
(43) Pub. Date: Jul. 23, 2026

(54) FLEXIBLE PIN

(71) Applicants: Dynex Semiconductor Limited, Lincoln (GB); Zhuzhou CRRC Times Semiconductor Co. Ltd, Zhuzhou, Hunan (CN)

(72) Inventors: Kongjing LI, Lincoln (GB); Yangang WANG, Lincoln (GB)

(21) Appl. No.: 19/141,688

(22) PCT Filed: Dec. 22, 2022
(86) PCT No.: PCT/EP2022/087536

§ 371 Date: Jun. 20, 2025

(51) Int. Cl. H01R 12/57; H01R 12/58; H01R 12/91; H10W 70/65; H10W 70/652

(52) U.S. Cl. CPC H01R 12/57; H01R 12/585; H01R 12/91; H10W 70/6525; H10W 70/6528; H10W 70/658

(57) ABSTRACT

A pin for use in power semiconductor packaging, the pin comprising: a head shaped to allow a connection to an external connector; a base comprising a surface suitable for soldering to a substrate of a semiconductor package; and a body connecting the head to the base, the body having a first side and opposite second side; wherein the body comprises a rigid portion and a flexible portion, the flexible portion being in proximity to the base and comprising: a first recess in the first side, the first recess comprising two opposing first horizontal faces; a second recess in the second side, the second recess comprising two opposing second horizontal faces; and an interior cavity separated from either side, the interior cavity comprising two opposing vertical faces; such that the flexible portion is able to flex, allowing for relative motion of the head and the base.

### FIELD OF THE DISCLOSURE

The disclosure relates to a pin, particularly but not exclusively to a press-fit pin for use in power semiconductor packaging.

### BACKGROUND

Semiconductor devices are often enclosed in packaging to protect delicate components. Pins are generally provided to allow connections between semiconductor components within the packaging and other external devices, each pin consisting of a head and a base joined by a rigid body. These pins must be attached to the internal device somehow, typically by soldering the base of the pin to a substrate. The body of the pin generally then protrudes through a hole in the packaging so that the head is outside the packaging, allowing connections to be made between the head and external devices. The pin is not generally soldered or attached anywhere except at the base.

Within this context, press-fit pin heads are commonly preferred for their ease of use in making additional connections to a power semiconductor device. However, issues can arise wherein a force applied to the head of a press-fit pin-for example, rough handling while attaching a connector-can result in the solder at the base of the pin being broken. Once this happens the pin cannot be used until the semiconductor packing is opened to permit access to the soldered connection for repairs.

FIG. 1 shows a packaged semiconductor module 100 according to the prior art, including a press-fit pin 102 protruding through a hole 104 in the module lid 106 allowing for external connections to be made to the pin head 108. The base 110 of the pin 102 is bonded to the semiconductor substrate 112, commonly using solder, ultrasound welding, or laser welding. The press-fit pin 102 may commonly be made from a material such as copper, while the substrate 112 may commonly be made from copper-ceramic-copper and the module lid 106 is commonly made from a polymer material.

There have been various attempts to alleviate this issue, for example by designing pins that have a degree of flexibility in a lower portion of the body of the pin. This may allow the body to flex somewhat, so that a force applied to the head may be accommodated by such flexion without damage to the pin base. It is noted that these attempts have often involved a degree of directionality, such that the pin has some ability to flex in a particular direction but not necessarily in other directions.

U.S. Pat. Nos. 10,559,905B2, 8,087,943B2, and 7,867,016B2 could be considered as prior art.

### SUMMARY

The inventors have recognised that there is a need for improved robustness of press-fit pins for semiconductor applications. In particular, it is desirable for the pin to be able to tolerate greater forces applied to the pin head without breaking the solder applied to the pin base, so that the failure rate of such pins is reduced. It is also desirable for a flexible pin to be able to be manufactured using methods that are as simple as possible, avoiding for example the need for complex bending of the pin during manufacture.

Implementations of the present disclosure provide a press-fit pin with enhanced resistance to external forces and a reduced chance of becoming detached during use, as well as a simpler manufacturing process compared to prior art designs.

According to one aspect of the present disclosure, there is provided a pin for use in power semiconductor packaging, the pin comprising: a head being shaped to allow a connection to an external connector; a base, wherein the base comprises a surface suitable for soldering to a substrate of a semiconductor package; and a body connecting the head to the base, the body having a first side and a second side, the second side opposite to the first side; wherein the body comprises a rigid portion and a flexible portion, the flexible portion being in proximity to the base; wherein the flexible portion comprises: a first recess in the first side, the first recess comprising two opposing first horizontal faces; a second recess in the second side, the second recess comprising two opposing second horizontal faces, the first and second horizontal faces being parallel to the surface of the base; and an interior cavity separated from either side, the interior cavity comprising two opposing vertical faces; such that the flexible portion is able to flex, allowing for relative motion of the head and the base.

This feature has the advantage of allowing the pin to flex when an external force is applied to the head, for example during the forming of a connection, thereby preventing such a force from being rigidly transmitted to the base. When the base is bonded (for example soldered) to a semiconductor substrate, this reduces the risk of the bond being broken during use. It is noted that the use of the first and second recesses and the interior cavity allows for compensation of external forces in any direction.

The flexible portion may be configured such that when a force is applied urging the head towards the base, the first horizontal faces, the second horizontal faces, and the vertical faces are urged nearer to one another.

The flexible portion may be configured such that when a force is applied urging the head towards the base, the first horizontal faces are urged nearer to one another, the second horizontal faces are urged nearer to one another, and the vertical faces are urged nearer to one another.

This feature has the advantage that a vertical force applied to the head is converted to a horizontal force between the vertical faces, thereby reducing the component of force applied to the base.

The flexible portion may be configured such that when a force larger than a threshold force is applied urging the head towards the base, the first horizontal faces, the second horizontal faces, and the vertical faces meet, thereby preventing further compression of the first recess, the second recess, or the hollow section.

The flexible portion may be configured such that when a force larger than the threshold force is applied urging the head towards the base, the first horizontal faces meet, the second horizontal faces meet, and the vertical faces meet, thereby preventing further compression of the first recess, the second recess, or the hollow section.

This feature has the advantage of limiting the maximum possible compression of the pin, thereby preventing, for example, the pin from being compressed until the head entirely enters a semiconductor packaging module and cannot be accessed.

The flexible portion may be configured such that when a force is applied urging the head away from the base, the first horizontal faces, the second horizontal faces, and the vertical faces are urged away from one another.

The flexible portion may be configured such that when a force is applied urging the head away from the base, the first horizontal faces are urged away from one another, the second horizontal faces are urged away from one another, and the vertical faces are urged away from one another.

This feature has the advantage that a vertical force applied to the head is converted to a horizontal force between the vertical faces, thereby reducing the component of force applied to the base.

The flexible portion may comprise one or more tilted outer edges.

This feature has the advantage of creating a horizontal component of force when a purely vertical force is applied to the pin head, thereby reducing the vertical force applied to the base in favour of increasing the horizontal force urging the opposing vertical faces together or apart.

The surface of the base may comprise a lower recess, such that when liquid solder is applied to the surface, the liquid solder climbs into the lower recess.

This feature has the advantage of allowing a stronger soldered bond between the base and a substrate.

The pin may be a press-fit pin.

The flexible portion may be wider than the rigid portion.

According to a further aspect of the present disclosure there is presented a semiconductor packaging module comprising: a substrate; a module frame enclosing the substrate, the module frame comprising a hole; and the pin of any preceding claim; wherein the base of the pin is soldered to the substrate; wherein the rigid portion of the pin extends through the hole, such that the head of the pin is outside the module frame.

The flexible portion may be wider than the hole such that no part of the flexible portion can enter the hole.

This feature has the advantage of limiting the maximum possible extension of the pin, thereby limiting the maximum extensive force that can be applied to the base. Damage to any bond between the base and a substrate due to excessive pulling on the pin head is thereby prevented.

According to a further aspect of the present disclosure there is presented a method of manufacturing a pin for use in power semiconductor packaging, the method comprising: forming a head shaped to allow a connection to an external connector; forming a base comprising a surface suitable for soldering to a substrate of a semiconductor package; forming a body connecting the head to the base, the body having a first side and a second side, the second side opposite to the first side; wherein the body comprises a rigid portion and a flexible portion, the flexible portion being in proximity to the base; forming a first recess in the flexible portion in the first side, the first recess comprising two opposing first horizontal faces; forming a second recess in the flexible portion in the second side, the second recess comprising two opposing second horizontal faces, the first and second horizontal faces being parallel to the surface of the base; and forming an interior cavity in the flexible portion separated from either side, the interior cavity comprising two opposing vertical faces; such that the flexible portion is able to flex, allowing for relative motion of the head and the base.

At least one of forming the first recess, forming the second recess, and forming the interior cavity may comprise a stamping process.

This has the advantage that stamping is a simple and cheap process compared to, for example, bending of the pin during manufacture.

These and other aspects will be apparent from the implementations described in the following. The scope of the present disclosure is not intended to be limited by this summary nor to implementations that necessarily solve any or all of the disadvantages noted.

### BRIEF DESCRIPTION OF THE DRAWINGS

For a better understanding of the present disclosure and to show how implementations may be put into effect, reference is made to the accompanying drawings in which:

FIG. 1 shows a schematic diagram of a packaged power semiconductor device according to the prior art;

FIG. 2 shows a pin for use in power semiconductor packaging;

FIG. 3 shows an angled view of the pin of FIG. 2;

FIG. 4 shows a schematic close-up view of the pin of FIG. 2 protruding through a hole in semiconductor packaging;

FIG. 5 shows a side view of an alternative pin for use in power semiconductor packaging; and

FIG. 6 shows an angled view of the pin of FIG. 5.

### DETAILED DESCRIPTION

Implementations will now be described by way of example only.

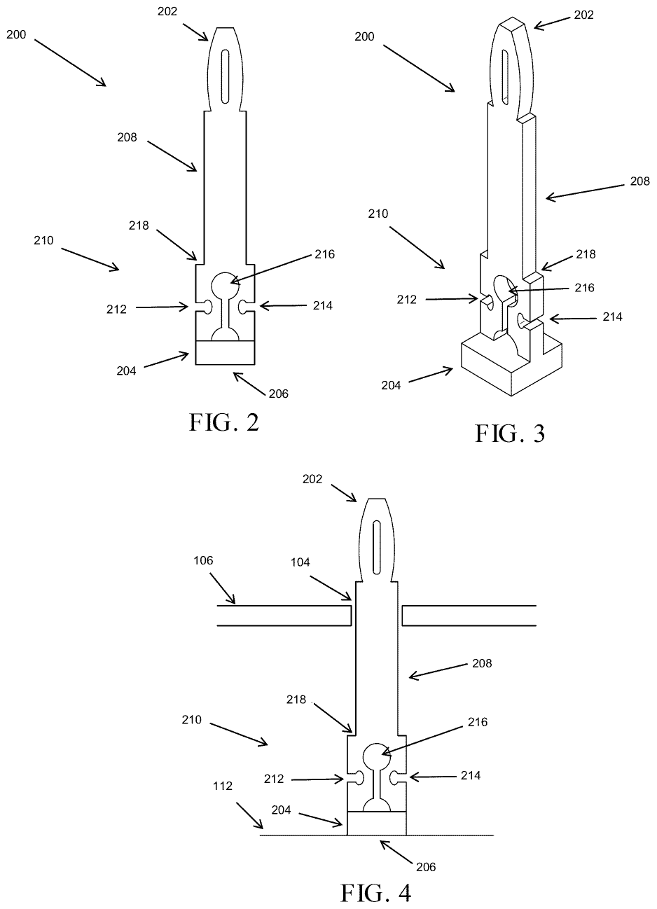

FIG. 2 shows a pin 200 suitable for use with a packaged semiconductor device, the pin 200 comprising a head 202 and a base 204. The head 202 of the pin 200 may be shaped to allow press-fit connections, while the base 204 may have a lower surface 206 suitable for soldering to a substrate as part of a packaged semiconductor device. The head 202 and base 204 are joined by a body divided into two portions: a rigid portion 208 and a flexible portion 210. The rigid portion 208 is envisioned to be relatively solid and inflexible apart from the inherent flexibility of the material. The flexible portion 210, however, is shaped to allow greater flexibility.

In particular, the flexible portion 210 comprises three flexibility-enhancing features: two recesses 212 and 214 (also referred to herein as a first recess and a second recess) in opposing sides of the flexible portion 210, and an interior cavity 216. Each of the recesses 212, 214 comprises a pair of opposing parallel surfaces disposed horizontally (also referred to herein as first and second horizontal faces). The interior cavity 216 comprises a pair of opposing vertical surfaces (also referred to herein as vertical faces).

For clarity, it is noted that in the above paragraph “vertical” is used to mean parallel to the length of the pin 200, so that “horizontal” means perpendicular to this direction. In other words, “horizontal” is used to mean parallel to the lower surface 206 of the base 204, with “vertical” being perpendicular to this direction.

The flexible portion 210 allows for a degree of relative motion of the head 202 and base 204 of the pin 200. For example, if a compressive force is exerted on the head 202 such that the head 202 is urged towards the base 204, it will be appreciated that this can be accommodated by partial collapse of the flexible region 210. In particular, the recesses 212, 214 and cavity 216 may partly collapse by means of the three pairs of opposing surfaces all moving closer together. The force may thereby be accommodated by the flexible portion 210 with reduced risk of damage to any bond, such as a soldered bond, between the lower surface 206 of the base 204 and a substrate.

Correspondingly, if an extensive force is applied to the head 202, urging the head 202 away from the base 204, a degree of extension of the flexible portion 210 may occur by the three pairs of opposing surfaces moving further apart.

In some implementations, it is particularly noted that a vertical force applied to the head 202 may thereby become a horizontal force urging the opposing vertical faces of the interior cavity 216 together or apart. This conversion to a horizontal force prevents the vertical force applied to the head 202 from being directly applied to the base 204. Therefore, any soldered bond between the lower surface 206 of the base 204 and a substrate is less likely to be broken by the applied vertical force.

The flexible portion 210 may similarly accommodate a lateral force applied to the head 202. In this scenario, the three pairs of opposing surfaces of the recesses 212, 214 and the cavity 216 may acquire a relative angle between the faces of each pair, such that the flexible portion 210 is able to tile and accommodate a lateral force. The effect of the force on any bond between the lower surface 206 of the base 204 and a substrate may be thereby mitigated.

The flexible portion 210 may therefore accommodate a force applied to the head 202 in any direction, due to the presence of the two opposed recesses 212, 214 and the cavity 216.

It is noted that a sufficiently large compressive force applied to the head 202 may cause the three pairs of opposing surfaces of the recesses 212, 214 and the cavity 216 to meet, such that the recesses 212, 214 and the cavity 216 are at least partially closed. In this eventuality, it may be impossible for the flexible region 210 to compress any further, such that the flexible region 210 effectively becomes rigid. This state therefore represents a maximum compression of the flexible region 210, and therefore the pin 200.

It will be appreciated that the precise shapes and locations of the recesses 212, 214 and cavity 216 are unimportant to the function of the disclosure and need not, for instance, match precisely what is shown in FIG. 2. Indeed, it will be appreciated that a wide range of shapes in different locations may achieve the functionality described above.

When the flexible region 210 is compressed or extended, the deformation may be elastic or plastic depending on the scale of the deformation and the properties of the material that the pin 200 is made from. If the deformation is relatively minor, it is envisioned that the pin 200 will return to its original undeformed state when the force applied to the head 202 is removed.

It is noted that the flexible portion 210 may be wider than the rigid portion 208 as shown in FIG. 2, resulting in a lip 218 at the top of the flexible portion 210. In some implementations wherein the pin 200 is incorporated into semiconductor packaging, this may provide a limit to the extension of the flexible portion 210. This will be further described below with reference to FIG. 4.

FIG. 3 shows an angled view of the press-fit pin 200 allowing a clearer appreciation of the three-dimensional shape of the press-fit pin 200, particularly the recesses 212 and 214 and the cavity 216.

It can be seen more clearly in FIG. 3 how the flexible portion 210 is able to bend or lean in order to accommodate a lateral force applied to the head 202. For example, the first recess 212 may compress while the second recess 214 expands, allowing the flexible portion 210 to lean parallel to the wider direction of the pin 200. Alternatively, each of the first and second recesses 212, 214 may compress and one end and expand at the other, allowing the flexible portion 210 to lean parallel to the narrowest direction of the pin 200.

Additionally, it can be more clearly seen in FIG. 3 that the pin 200 has a constant cross-section. The recesses 212, 214 and cavity 216 can therefore be formed from a solid pin by stamping during manufacture. The pin 200 is therefore simpler to manufacture than prior art designs that require complex bending of a pin during production.

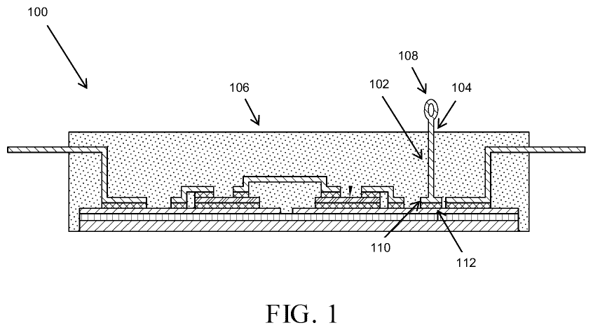

FIG. 4 shows a schematic of the press-fit pin of FIG. 2 inserted through a hole 104 in a semiconductor packaging module lid 106, in an arrangement comparable to that used for the prior art pin 102 of FIG. 1. The lower surface 206 of the base 204 of the press-fit pin 200 may be bonded to a substrate 112 of the module, for example by solder.

The lip 218, described above with reference to FIG. 2, may be designed to be wider than the hole 104. This may prevent the flexible portion 210 from being able to enter the hole 104. This may then provide a limit to the extension of the flexible portion 210, since when the lip 218 (i.e. the uppermost part of the flexible portion 210) meets the module lid 106, the flexible portion 210 is prevented from extending any further.

The height of the lip 218 compared to the lid 106 may be chosen such that this maximum possible extent is not sufficient to cause the flexible portion 210 to break from excessive deformation, and such that the force exerted on the base 204 at the position of maximum extension is not sufficient to damage the bond between the lower surface 206 and the substrate 112.

It is noted that, in some implementations, the semiconductor packaging module may be narrower than is shown in FIG. 4, so that the lip 218 is nearer to the module lid 106.

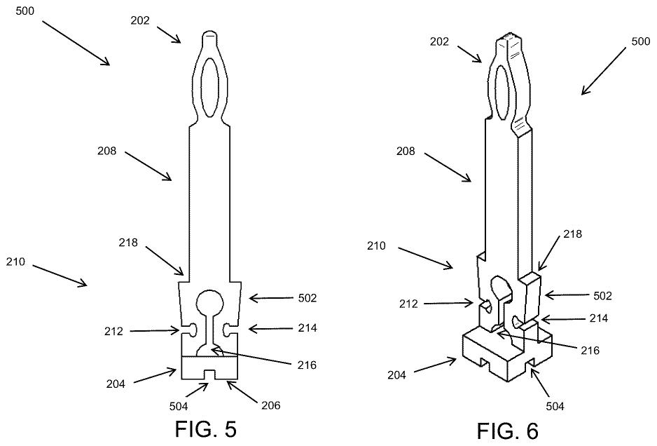

If the lower surface 206 of the base 204 comprises a lower recess 504 as described below with reference to FIG. 5, solder may climb into the lower recess to strengthen the bond between the substrate 112 and the lower surface 206.

FIG. 5 shows a further pin 500. The pin 500 has many features in common with the pin 200 discussed above, and the same reference numerals are used for these figures as were used above. The pin 500 generally includes the additional feature that the outer edges 502 of the flexible portion 210 are tilted at an angle. This tilt further facilitates the conversion of a vertical force applied to head 202 into a horizontal force, as discussed above with reference to FIG. 2, thereby further reducing the vertical force transmitted to the base 204 in favour of an increased horizontal force acting to collapse the cavity 216.

The pin 500 further generally includes a recess 504 in the surface 206 of the base 504, otherwise referred to herein as a lower recess 504. The lower recess 504 may act as a solder climbing feature. That is, the lower recess 504 may allow solder disposed between the surface 206 and a substrate to more firmly bond with the surface 206 by presenting an increased surface area for contact with the solder.

It will be appreciated that the tiled edges 502 need not necessarily be accompanied by the lower recess 504. Indeed, it is envisioned that a pin may be provided resembling the pin 200 shown in FIG. 2, but including either the tilted walls 502 or the recess 504, without necessarily including both as the pin 500 does.

FIG. 6 shows an angled view of the pin 500 to allow a better appreciation of the three-dimensional nature of the pin 500.

Thus, it can be seen that the implementations described herein provide a press-fit pin that is more robust to external forces and less likely to become detached during use.

The skilled person will understand that in the preceding description and appended claims, positional terms such as ‘upper’, ‘lower’, ‘above’, ‘overlap’, ‘under’, ‘lateral’, etc. are made with reference to conceptual illustrations of an apparatus, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A pin for use in power semiconductor packaging, the pin comprising:
a head being shaped to allow a connection to an external connector;
a base, wherein the base comprises a surface suitable for soldering to a substrate of a semiconductor package; and
a body connecting the head to the base, the body having a first side and a second side, the second side opposite to the first side;
wherein the body comprises a rigid portion and a flexible portion, the flexible portion being in proximity to the base;
wherein the flexible portion comprises:
a first recess in the first side, the first recess comprising two opposing first horizontal faces;
a second recess in the second side, the second recess comprising two opposing second horizontal faces, the first and second horizontal faces being parallel to the surface of the base; and
an interior cavity separated from either side, the interior cavity comprising two opposing vertical faces;
such that the flexible portion is able to flex, allowing for relative motion of the head and the base.

2. The pin of claim 1, wherein the flexible portion is configured such that when a force is applied urging the head towards the base, the first horizontal faces, the second horizontal faces, and the vertical faces are urged nearer to one another.

3. The pin of claim 2, wherein the flexible portion is configured such that when a force is applied urging the head towards the base, the first horizontal faces are urged nearer to one another, the second horizontal faces are urged nearer to one another, and the vertical faces are urged nearer to one another.

4. The pin of claim 2, wherein the flexible portion is configured such that when a force larger than a threshold force is applied urging the head towards the base, the first horizontal faces, the second horizontal faces, and the vertical faces meet, thereby preventing further compression of the first recess, the second recess, or the hollow section.

5. The pin of claim 4, wherein the flexible portion is configured such that when a force larger than the threshold force is applied urging the head towards the base, the first horizontal faces meet, the second horizontal faces meet, and the vertical faces meet, thereby preventing further compression of the first recess, the second recess, or the hollow section.

6. The pin of claim 1, wherein the flexible portion is configured such that when a force is applied urging the head away from the base, the first horizontal faces, the second horizontal faces, and the vertical faces are urged away from one another.

7. The pin of claim 6, wherein the flexible portion is configured such that when a force is applied urging the head away from the base, the first horizontal faces are urged away from one another, the second horizontal faces are urged away from one another, and the vertical faces are urged away from one another.

8. The pin of claim 1, wherein the flexible portion comprises one or more tilted outer edges.

9. The pin of claim 1, wherein the surface of the base comprises a lower recess, such that when liquid solder is applied to the surface, the liquid solder climbs into the lower recess.

10. The pin of claim 1, wherein the pin is a press-fit pin.

11. The pin of claim 1, wherein the flexible portion is wider than the rigid portion.

12. A semiconductor packaging module comprising:
a substrate;
a module frame enclosing the substrate, the module frame comprising a hole; and
the pin of claim 1;
wherein the base of the pin is soldered to the substrate;
wherein the rigid portion of the pin extends through the hole, such that the head of the pin is outside the module frame.

13. The semiconductor packaging module of claim 12, wherein the flexible portion is wider than the rigid portion, and wherein the flexible portion is wider than the hole such that no part of the flexible portion can enter the hole.

14. A method of manufacturing a pin for use in power semiconductor packaging, the method comprising:
forming a head shaped to allow a connection to an external connector;
forming a base comprising a surface suitable for soldering to a substrate of a semiconductor package;
forming a body connecting the head to the base, the body having a first side and a second side, the second side opposite to the first side; wherein the body comprises a rigid portion and a flexible portion, the flexible portion being in proximity to the base;
forming a first recess in the flexible portion in the first side, the first recess comprising two opposing first horizontal faces;
forming a second recess in the flexible portion in the second side, the second recess comprising two opposing second horizontal faces, the first and second horizontal faces being parallel to the surface of the base; and
forming an interior cavity in the flexible portion separated from either side, the interior cavity comprising two opposing vertical faces;
such that the flexible portion is able to flex, allowing for relative motion of the head and the base.

15. The method of claim 14, wherein at least one of forming the first recess, forming the second recess, and forming the interior cavity comprises a stamping process.
